(19) United States
(12) Patent Application Publication
(10) Pub. No.: US 2026/0074008 A1
(43) Pub. Date: Mar. 12, 2026

(54) REPAIR VERIFICATION CIRCUIT AND SEMICONDUCTOR APPARATUS INCLUDING THE REPAIR VERIFICATION CIRCUIT

(71) Applicant: SK hynix Inc., Icheon-si Gyeonggi-do (KR)

(72) Inventors: Hyeong Soo JEONG, Icheon-si Gyeonggi-do (KR); Byeong Cheol LEE, Icheon-si Gyeonggi-do (KR)

(73) Assignee: SK hynix Inc., Icheon-si Gyeonggi-do (KR)

(21) Appl. No.: 19/055,289

(22) Filed: Feb. 17, 2025

(30) Foreign Application Priority Data
Sep. 11, 2024 (KR) 10-2024-0124143

(51) Int. Cl. G11C 29/00; G11C 29/12

(52) U.S. Cl. CPC G11C 29/76; G11C 29/1201; G11C 29/789

(57) ABSTRACT

A repair verification circuit includes a repair address storage circuit and a redundancy flag generation circuit. The repair address storage circuit stores at least one repair address and generates a comparison result merge signal by comparing the at least one repair address with an external input address. The redundancy flag generation circuit generates a redundancy flag by latching the comparison result merge signal in response to a first control signal generated according to an active command.

### CROSS-REFERENCES TO RELATED APPLICATION

The present application claims priority under 35 U.S.C. § 119(a) to Korean application number 10-2024-0124143 filed on Sep. 11, 2024, in the Korean Intellectual Property Office, which application is incorporated herein by reference in its entirety.

### BACKGROUND

### 1. Technical Field

Various embodiments generally relate to a semiconductor circuit, and, more particularly, to a repair verification circuit capable of verifying whether a repair operation is performed normally, and to a semiconductor apparatus including the same.

### 2. Related Art

A semiconductor apparatus may detect a defective memory cell (hereinafter referred to as a defective cell) by testing. The semiconductor apparatus is configured to determine if an externally provided address is an address (hereinafter referred to as a repair address) for accessing a defective cell, and if so, to perform a repair operation to access a redundant memory cell (hereinafter referred to as a redundant cell) instead of the defective cell.

The repair operation is performed by a repair circuit that replaces a row and/or a column associated with the defective cell with a row redundancy and/or a column redundancy corresponding to a redundant cell in order to access the redundant cell.

There are cases in which the repair operation is not performed normally due to a malfunction of the repair circuit, etc., and it is difficult to accurately confirm whether the repair operation is performed accurately from outside the semiconductor apparatus. Therefore, there is a need to develop a technology to confirm whether the repair operation is performed accurately, i.e., whether a row redundancy and a column redundancy are used.

### SUMMARY

In an embodiment, a repair verification circuit may include a repair address storage circuit and a redundancy flag generation circuit. The repair address storage circuit may be configured to store at least one repair address, and may be configured to generate a comparison result merge signal by comparing the at least one repair address with an external input address. The redundancy flag generation circuit may be configured to generate a redundancy flag by latching the comparison result merge signal in response to a first control signal generated according to an active command.

In an embodiment, a semiconductor apparatus may include a memory core, a repair verification circuit, and an OTP memory circuit. The memory core may include a plurality of memory cells. The repair verification circuit may be configured to compare an external input address and at least one repair address to generate a comparison result merge signal, may be configured to latch the comparison result merge signal in accordance with a first control signal generated in response to an active command to generate a redundancy flag, and may be configured to output the redundancy flag in accordance with a second control signal generated in response to a read command. The OTP memory circuit may be configured to store the at least one repair address corresponding to at least one memory cell determined to be defective among the plurality of memory cells, and may be configured to transmit the at least one stored repair address to the repair verification circuit.

### BRIEF DESCRIPTION OF THE DRAWINGS

FIG. 1 is a diagram illustrating a repair verification circuit according to an embodiment of the present disclosure.

FIG. 2 is a diagram illustrating a repair address storage circuit of FIG. 1.

FIG. 3 is a diagram illustrating a first address latch set of FIG. 2.

FIG. 4 is a diagram illustrating a comparison result merge circuit of FIG. 2.

FIG. 5 is a diagram illustrating a redundancy flag generation circuit of FIG. 1.

FIG. 6 is a diagram illustrating a redundancy flag output circuit of FIG. 1.

FIG. 7 is a diagram illustrating a selection circuit of FIG. 1.

FIG. 8 is a diagram illustrating a semiconductor apparatus according to an embodiment of the present disclosure.

FIG. 9 is a diagram illustrating a unit memory region of FIG. 8.

FIG. 10 is a diagram illustrating a repair verification operation of a semiconductor apparatus according to an embodiment of the present disclosure.

### DETAILED DESCRIPTION

Various embodiments of the present disclosure can externally verify whether a repair operation is performed correctly, which can facilitate the failure analysis of a semiconductor apparatus, reduce test time, and improve the operational reliability of the semiconductor apparatus.

Hereinafter, embodiments of the present disclosure will be described in more detail with reference to the accompanying drawings.

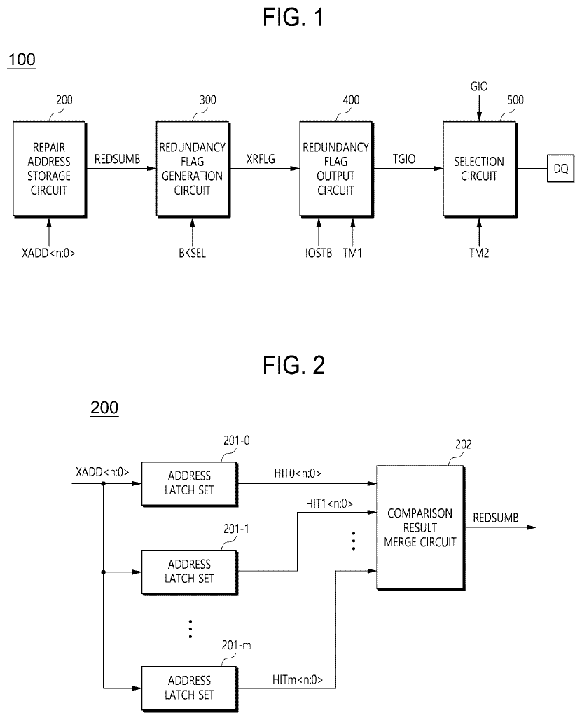

FIG. 1 is a diagram illustrating a repair verification circuit 100 according to an embodiment of the present disclosure.

Referring to FIG. 1, the repair verification circuit 100 may include a repair address storage circuit 200 and a redundancy flag generation circuit 300. The repair verification circuit 100 may further include a redundancy flag output circuit 400 and a selection circuit 500.

The repair address storage circuit 200 may store at least one repair address and may compare an external input address XADD<n:0> with the at least one repair address to generate a comparison result merge signal REDSUMB. ‘n’ may be defined as a non-negative integer. The at least one repair address may have different values.

The redundancy flag generation circuit 300 may receive the comparison result merge signal REDSUMB and a first control signal BKSEL, the first control signal BKSEL generated in accordance with an active command, and may output a redundancy flag XRFLG. The redundancy flag generation circuit 300 may latch the comparison result merge signal REDSUMB according to the first control signal BKSEL to generate the redundancy flag XRFLG. The first control signal BKSEL may include a signal that selects a unit memory region, such as a memory bank, after a predetermined time after the active command is input.

The redundancy flag output circuit 400 may output the redundancy flag XRFLG to a test global line TGIO in response to a second control signal IOSTB generated in response to a read command. The second control signal IOSTB may include a signal that controls an operation of an input/output sense amplifier to drive input/output lines associated with a memory bank after a predetermined time after the read command is input. The word “predetermined” as used herein with respect to a parameter, such as a predetermined timing, time, or voltage level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

Based on a second test mode signal TM2, the selection circuit 500 may output one of a signal transmitted through a global line GIO and a signal transmitted through the test global line TGIO through an input/output pad DQ.

FIG. 2 is a diagram illustrating the repair address storage circuit 200 of FIG. 1.

Referring to FIG. 2, the repair address storage circuit 200 may include a plurality of address latch sets 201-0 to 201-m and a comparison result merge circuit 202.

The plurality of address latch sets 201-0 to 201-m may store different repair addresses and may output a plurality of comparison result signal sets HIT0<n:0>, HIT1<n:0>, . . . , HITm<n:0> by comparing the different repair addresses with the external input address XADD<n:0>, respectively. ‘m’ may be defined as a non-negative integer. The plurality of address latch sets 201-0 to 201-m may be configured similarly. For example, the first address latch set 201-0 may store a first repair address, compare the first repair address to the external input address XADD<n:0>, and output a first comparison result signal set HIT0<n:0>. The second address latch set 201-1 may store a second repair address, compare the second repair address with the external input address XADD<n:0>, and output a second comparison result signal set HIT1<n:0>. The (m+1)th address latch set 201-m may store an (m+1)th repair address, compare it with the external input address XADD<n:0>, and output an (m+1)th comparison result signal set HITm<n:0>. Before further explanation, repair addresses stored in an OTP memory circuit in a boot-up period of a semiconductor apparatus may be stored in the plurality of address latch sets 201-0 to 201-m.

The comparison result merge circuit 202 may generate the comparison result merge signal REDSUMB according to the plurality of comparison result signal sets HIT<m:0><n:0>. The comparison result merge circuit 202 may logically combine the plurality of comparison result signal sets HIT<m:0><n:0> to generate the comparison result merge signal REDSUMB.

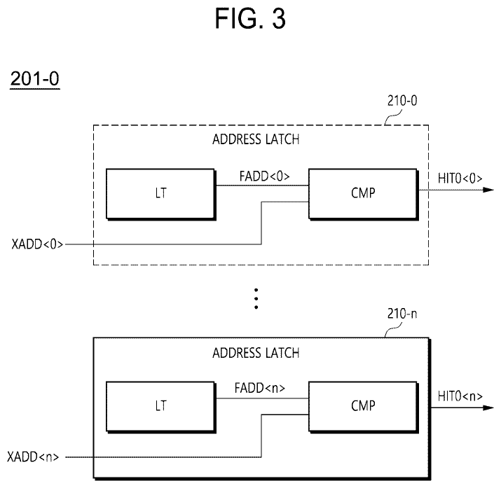

FIG. 3 is a diagram illustrating the first address latch set 201-0 of FIG. 2.

Referring to FIG. 3, the first address latch set 201-0 may include a plurality of address latches 210-0 to 210-n. The plurality of address latches 210-0 to 210-n may be configured similarly.

For example, the first address latch 210-0 may store a first bit FADD<0> of the first repair address FADD.<n:0> The first address latch 210-0 may compare the first bit FADD<0> of the first repair address FADD<n:0> with a first bit XADD<0> of the external input address XADD<n:0> and may output a first bit HIT0<0> of the first comparison result signal set HIT0<n:0>. The first address latch 210-0 may include a latch LT and a comparison circuit CMP. The latch LT may store the first bit FADD<0> of the first repair address FADD<n:0>. The comparison circuit CMP compare the first bit FADD<0> of the first repair address FADD<n:0> with the first bit XADD<0> of the external input address XADD<n:0> and may output the first bit HIT0<0> of the first comparison result signal set HIT0<n:0>. The comparison circuit 212 may output the first bit HIT0<0> of the first comparison result signal set HIT0<n:0> at a high level when a logic level of the first bit FADD<0> of the first repair address FADD<n:0> and a logic level of the first bit XADD<0> of the external input address XADD<n:0> match.

The (n+1)th address latch 210-n may store an (n+1)th bit FADD<n> of the first repair address FADD<n:0>. The (n+1)th address latch 210-n may compare the (n+1)th bit FADD<n> of the first repair address FADD<n:0> with an (n+1)th bit XADD<n> of the external input address XADD<n:0> and may output an (n+1)th bit HIT0<n> of the first comparison result signal set HIT0<n:0>.

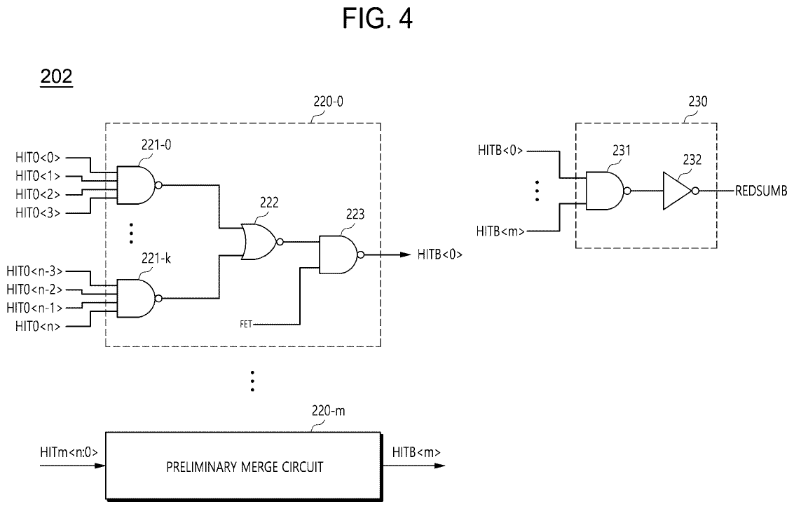

FIG. 4 is a diagram illustrating the comparison result merge circuit 202 of FIG. 2.

Referring to FIG. 4, the comparison result merge circuit 202 may include a plurality of preliminary merge circuits 220-0 to 220-m and a main merge circuit 230.

The plurality of preliminary merge circuits 220-0 to 220-m may logically combine each of the plurality of comparison result signal sets HIT0<n:0>, HIT1<n:0>, . . . , HITm<n:0> to generate a plurality of preliminary merge signals HITB<m:0>. The plurality of preliminary merge circuits 220-0 to 220-m may be configured similarly. For example, the first preliminary merge circuit 220-0 may logically combine a first comparison result signal set HIT0<n:> to generate a first preliminary merge signal HITB<0>. The (m+1)th preliminary merge circuit 220-m may logically combine an (m+1)th comparison result signal set HITm<n:0> to generate an (m+1)th preliminary merge signal HITB<m>. The first preliminary merge circuit 220-0 may include a plurality of logic gates 221-0 to 221-k, 222, and 223. Each of the logic gates 221-0 to 221-k may perform a NAND operation on a predetermined number of bits of the first comparison result signal set HIT<0><n:0> and may output its result. For example, the predetermined number of bits may be four bits. The logic gate 222 may perform a NOR operation on outputs of the logic gates 221-0 to 221-k and may output its result. The logic gate 223 may perform a NAND operation on an output of the logic gate 222 and a fuse enable signal FET and may output the first preliminary merge signal HITB<0>. The logic level of the fuse enable signal FET may indicate whether a storage circuit for storing a repair address corresponding to the first comparison result signal set HIT0<n:> is enabled or disabled. The storage circuit may include, for example, a one-time programmable OTP memory circuit as a separate configuration from the repair verification circuit 100 according to an embodiment of the present disclosure. Units of storage in the storage circuit, for example, electronic fuses, may set the fuse enable signal FET to a high level if the electronic fuses are programmed to match the repair address corresponding to the first comparison result signal set HIT0<n:>. If the electronic fuses are not programmed, the fuse enable signal FET may be set to a low level. The first preliminary merge circuit 220-0 may output the first preliminary merge signal HITB<0> at a low level when the first comparison result signal set HIT<0><n:0> are all at a high level, i.e., when the logic levels of the first repair address FADD<n:0> and the logic levels of the external input address XADD<n:0> match each other.

The main merge circuit 230 may perform an AND operation on the plurality of preliminary merge signals HITB<m:0> and may output its result as the comparison result merge signal REDSUMB. The main merge circuit 230 may include a first logic gate 231 and a second logic gate 232. The main merge circuit 230 may output the comparison result merge signal REDSUMB at a low level if any of the plurality of preliminary merge signals HITB<m:0> is at a low level.

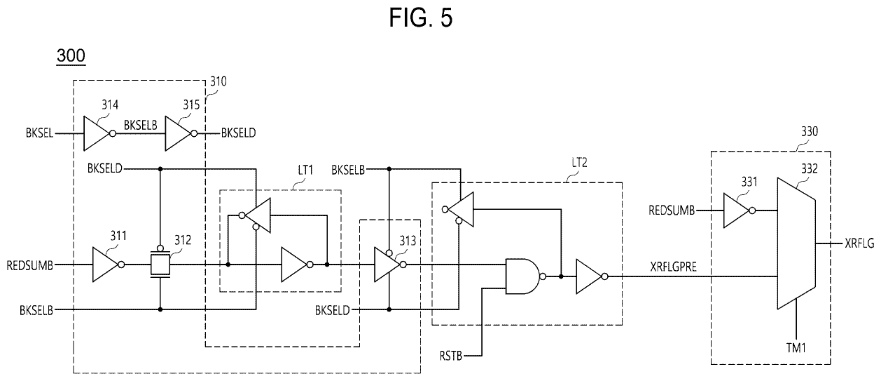

FIG. 5 is a diagram illustrating the redundancy flag generation circuit 300 of FIG. 1.

Referring to FIG. 5, the redundancy flag generation circuit 300 may include a latch timing control circuit 310. The redundant flag generation circuit 300 may further include a flag selection circuit 330.

The latch timing control circuit 310 may receive and latch the comparison result merge signal REDSUMB according to the first control signal BKSEL and may output a preliminary redundancy flag XRFLGPRE. The latch timing control circuit 310 may include a plurality of logic gates 311 to 315.

The first logic gate 311 may invert the comparison result merge signal REDSUMB and may output its result. The second logic gate 312 may pass an output of the first logic gate 311 when a first phase adjustment control signal BKSELB is at a high level and a second phase adjustment control signal BKSELD is at a low level. Because the first phase adjustment control signal BKSELB and the second phase adjustment control signal BKSELD are in opposite phases of each other, a description of a logic level of the second phase adjustment control signal BKSELD will be omitted hereinafter. A first latch LT1 may latch an output of the second logic gate 312 when the first phase adjustment control signal BKSELB is at a low level. When the first phase adjustment control signal BKSELB is at a low level, the third logic gate 313 may invert an output of the first latch LT1 and may output its result. A second latch LT2 may latch an output of the third logic gate 313 when the first phase adjustment control signal BKSELB is at a high level and may output the preliminary redundancy flag XRFLGPRE by inverting the latched signal. The second latch LT2 may reset the preliminary redundancy flag XRFLGPRE to a low level when a reset signal RSTB is enabled to a low level. The fourth logic gate 314 may output the first phase adjustment control signal BKSELB by inverting the first control signal BKSEL. The fifth logic gate 315 may output the second phase adjustment control signal BKSELD by inverting the first phase adjustment control signal BKSELB.

The flag selection circuit 330 may select one of the comparison result merge signal REDSUMB that is inverted and the preliminary redundancy flag XRFLGPRE according to the first test mode signal TM1 and may output the redundancy flag XRFLG. The first test mode signal TM1 may be used as a signal to determine whether a first test mode is activated for outputting the preliminary redundancy flag XRFLGPRE as the redundancy flag XRFLG. The first test mode signal TM1 may be a high level to activate the first test mode and a low level to deactivate the first test mode.

The flag selection circuit 330 may include a logic gate 331 and a multiplexer 332. The logic gate 331 may invert the comparison result merge signal REDSUMB and may output its result. Based on the first test mode signal TM1, the multiplexer 332 may output one of an output of the logic gate 331 and the preliminary redundancy flag XRFLGPRE as the redundancy flag XRFLG. The multiplexer 332 may output the preliminary redundancy flag XRFLGPRE as the redundancy flag XRFLG when the first test mode signal TM1 is at a high level and may output the comparison result merge signal REDSUMB as the redundancy flag XRFLG when the first test mode signal TM1 is at a low level.

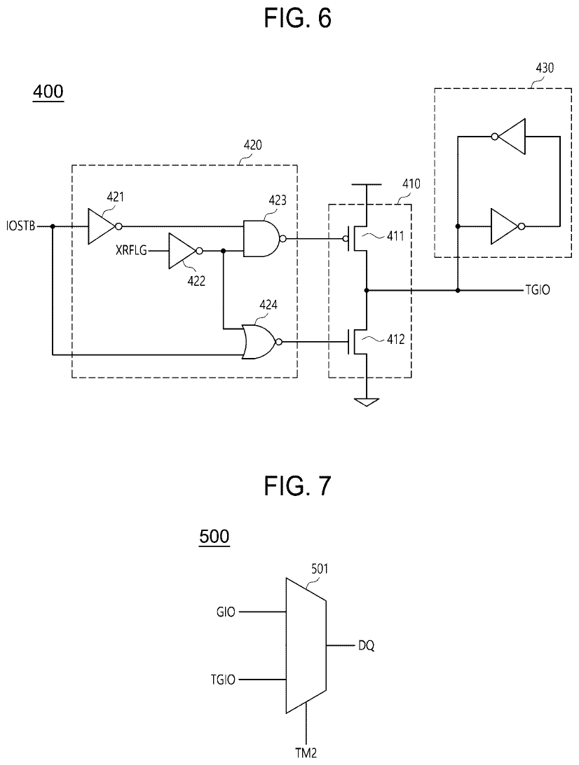

FIG. 6 is a diagram illustrating the redundancy flag output circuit 400 of FIG. 1.

Referring to FIG. 6, the redundancy flag output circuit 400 may include a driving circuit 410 and a driving control circuit 420. The redundant flag output circuit 400 may further include a latch 430.

The driving circuit 410 may pull the test global line TGIO up to a power level or may pull it down to a ground level. The driving circuit 410 may include a first transistor 411 coupled between a power source and the test global line TGIO and a second transistor 412 coupled between the test global line TGIO and a ground terminal.

The driving control circuit 420 may control an operation of the driving circuit 410 in response to the redundancy flag XRFLG and the second control signal IOSTB. The driving control circuit 420 may include a plurality of logic gates 421 to 424. The first logic gate 421 may invert the second control signal IOSTB and may output its result. The second logic gate 422 may invert the redundancy flag XRFLG and may output its result. The third logic gate 423 may pull up the test global line TGIO to a power level by controlling the first transistor 411 of the driving circuit 410 based on a result of performing a NAND operation on an output of the first logic gate 421 and an output of the second logic gate 422. The fourth logic gate 424 may pull the test global line TGIO down to a ground level by controlling the second transistor 412 of the driving circuit 410 based on a result of performing a NOR operation on the output of the second logic gate 422 and the second control signal IOSTB.

The latch 430 may maintain a logic level of the test global line TGIO until a transition of the logic level of the test global line TGIO is initiated by the driving circuit 410.

FIG. 7 is a diagram illustrating the selection circuit 500 of FIG. 1.

Referring to FIG. 7, the selection circuit 500 may include a multiplexer 501. Based on the second test mode signal TM2, the multiplexer 501 may output one of a signal from the global line GIO and a signal from the test global line TGIO to the input/output pad DQ. The second test mode signal TM2 may be used as a signal to determine an activation of the second test mode for performing test read operation. The second test mode signal TM2 may be at a high level upon the activation of the second test mode and a low level upon a deactivation of the second test mode.

When the second test mode signal TM2 is at a high level, the multiplexer 501 may output a signal from the test global line TGIO, i.e., the redundancy flag XRFLG, to the input/output pad DQ. When the second test mode signal TM2 is at a low level, the multiplexer 501 may output a signal from the global line GIO, i.e., read data transmitted from memory region according to a read command, to the input/output pad DQ.

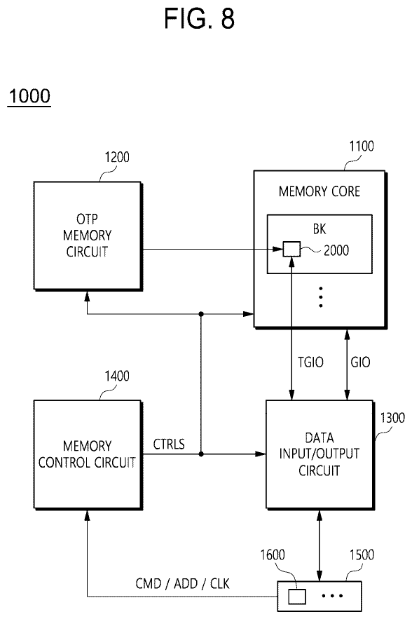

FIG. 8 is a diagram illustrating a semiconductor apparatus 1000 according to an embodiment of the present disclosure.

Referring to FIG. 8, the semiconductor apparatus 1000 may include a memory core 1100, a repair verification circuit 2000, an OTP memory circuit 1200, a data input/output circuit 1300, a memory control circuit 1400, and an input/output pad circuit 1500.

The memory core 1100 may include a plurality of memory cells, and the plurality of memory cells may include at least one of volatile memory and non-volatile memory. The volatile memory may include SRAM (Static RAM), DRAM (Dynamic RAM), SDRAM (Synchronous DRAM), and the non-volatile memory may include ROM (Read Only Memory), PROM (Programmable ROM), EEPROM (Electrically Erase and Programmable ROM), EPROM (Electrically Programmable ROM), flash memory, PRAM (Phase change RAM), MRAM (Magnetic RAM), RRAM (Resistive RAM), and FRAM (Ferroelectric RAM). The plurality of memory cells of the memory core 1100 may be divided into a plurality of unit memory regions, such as a plurality of memory banks BK.

The repair verification circuit 2000 may store at least one repair address, compare the at least one repair address with an external input address to generate a comparison result merge signal, latch the comparison result merge signal in response to a first control signal generated in response to an active command to generate a redundancy flag, and output the redundancy flag to a device external to the semiconductor apparatus 1000 through a test global line TGIO in response to a second control signal generated in response to a read command. The repair verification circuit 2000 may be configured like the repair verification circuit 100 described with reference to FIGS. 1 to 7. The repair verification circuit 2000 may be included in each of the plurality of memory banks BK.

The OTP memory circuit 1200 may store at least one repair address corresponding to defective cells detected based on test results of the semiconductor apparatus 1000. The OTP memory circuit 1200 may include a plurality of electronic fuses and may store the repair address by programming the plurality of electronic fuses to correspond to the repair address. The OTP memory circuit 1200 may transmit the at least one stored repair address to the repair verification circuit 2000 according to at least one of a plurality of control signals CTRLS. The OTP memory circuit 1200 may transmit the at least one stored repair address to the repair verification circuit 2000 during a boot-up operation of the semiconductor apparatus 1000 according to at least one of the plurality of control signals CTRLS.

The data input/output circuit 1300 may be coupled to the memory core 1100 through a global line GIO and a test global line TGIO. The data input/output circuit 1300 may be coupled to the repair verification circuit 2000 through the test global line TGIO. The data input/output circuit 1300 may exchange data with an external system or the memory core 1100 according to at least one of the plurality of control signals CTRLS. The data input/output circuit 1300 may include a configuration of the repair verification circuit 2000 that corresponds to the selection circuit 500 of FIG. 1, among other configurations. The data input/output circuit 1300 may output one of a signal of the global line GIO and a signal of the test global line TGIO to one of the plurality of pads 1600 of the input/output pad circuit 1500, such as a data input/output pad DQ.

The memory control circuit 1400 may be coupled to the memory core 1100, the OTP memory circuit 1200, and the data input/output circuit 1300. The memory control circuit 1400 may receive inputs, such as a command CMD, an address ADD, and a clock signal CLK. The memory control circuit 1400 may generate the plurality of control signals CTRLS to control a test operation and a normal operation of the semiconductor apparatus 1000. The test operation may include outputting a redundancy flag XRFLG through the test global line TGIO. The normal operation may include a read operation, a write operation, and an address processing operation. The plurality of control signals CTRLS may include the first control signal BKSEL, the second control signal IOSTB, the first test mode signal TM1, the second test mode signal TM2, and the reset signal RSTB.

The input/output pad circuit 1500 may include a plurality of pads 1600 for receiving the command CMD, the address ADD, and the clock signal CLK and for inputting and outputting data.

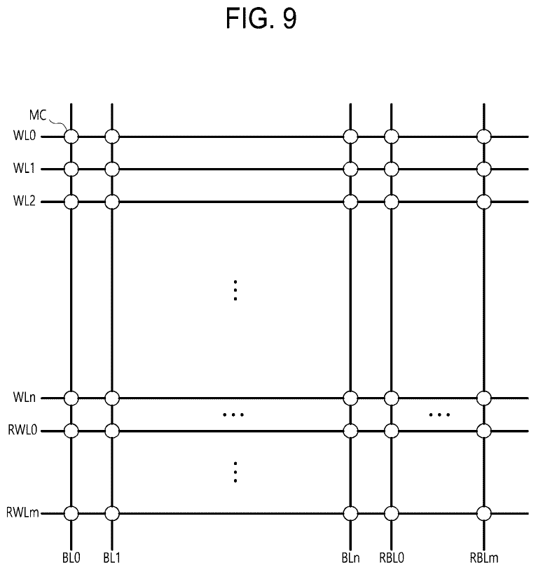

FIG. 9 is a diagram illustrating the unit memory region of FIG. 8.

Referring to FIG. 9, the unit memory region may be arranged such that a plurality of word lines WL0 to WLn and RWL0 to RWm and a plurality of bit lines BL0 to BLn and RBL0 to RBLm intersect, and a memory cell MC is formed at each intersection.

The plurality of word lines WL0 to WLn and RWL0 to RWm may be divided into normal word lines WL0 to WLn and row redundancies, i.e., redundant word lines RWL0 to RWm. The plurality of bit lines BL0-BLn and RBL0-RBLm may be divided into normal bit lines BL0 to BLn and column redundancies, i.e., redundant bit lines RBL0 to RBLm.

If the memory cell MC formed in an intersection region of the normal word lines WL and the normal bit lines BL is determined to be a defective cell during a test operation, a repair operation may be performed in which the defective cell is replaced with a memory cell formed in an intersection region of one of the redundant word lines RWL0 to RWm and one of the redundant bit lines RBL0 to RBLm.

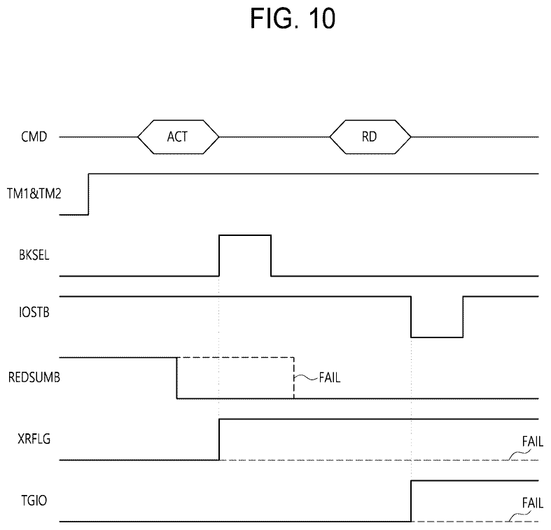

FIG. 10 is a diagram illustrating a repair verification operation of the semiconductor apparatus 1000 according to an embodiment of the present disclosure.

During a boot-up operation period of the semiconductor apparatus 1000, at least one repair address stored in the OTP memory circuit 1200 may be passed to and stored in the repair verification circuit 2000.

Following the boot-up operation, the semiconductor apparatus 1000 may enter a test mode in response to an external command.

Upon entering the test mode for repair verification, the first test mode signal TM1 and the second test mode signal TM2 may be enabled at a high level.

The external input address XADD<n:0> may change value, and an active command ATC may be entered to proceed with the repair verification test.

Because a repair address has already been determined during a previous test, i.e. during a test to determine a defective cell, an expected value of the comparison result merge signal REDSUMB according to the external input address XADD<n:0> may already be known.

For example, assume that the comparison result merge signal REDSUMB according to a previously input external input address XADD<n:0> is at a high level, and the expected value of the comparison result merge signal REDSUMB according to a currently input external input address XADD<n:0> is at a low level.

As the active command ACT is input, the first control signal BKSEL may be activated to a high level after a predetermined time.

The repair verification circuit 2000 may compare the external input address XADD<n:0> input with the active command ACT with each of the at least one stored repair address and may merge comparison results to generate the comparison result merge signal REDSUMB (see FIG. 4). When the repair verification circuit 2000 and circuits in a signal path associated therewith are operating normally, the comparison result merge signal REDSUMB may transition to a low level before the first control signal BKSEL is activated to a high level.

At the time the first control signal BKSEL is activated to a high level, the redundancy flag XRFLG may transition to a high level because the comparison result merge signal REDSUMB is at a low level (see FIG. 5).

The second control signal IOSTB may be enabled to a high level after a predetermined time as a read command RD is input.

As the second control signal IOSTB is activated to a high level, the redundancy flag XRFLG with a high level may be output to a device external to the semiconductor apparatus 1000 through the test global line TGIO and the input/output pad DQ.

The device external to the semiconductor apparatus 1000, for example, a test equipment, may confirm that a repair operation was successful based on a high-level redundancy flag XRFLG equal to an expected value.

On the other hand, if at least one of the repair verification circuit 2000 and circuits in a signal path associated therewith fails to operate normally, the comparison result merge signal REDSUMB might not transition to a low level and may remain at a high level even after the first control signal BKSEL is activated to a high level or may transition to a low level after the first control signal BKSEL is deactivated to a low level.

At the time the first control signal BKSEL is enabled to a high level, the redundancy flag XRFLG may remain at a low level because the comparison result merge signal REDSUMB is at a high level (see FIG. 5).

The second control signal IOSTB may be enabled to a high level after a predetermined time as the read command RD is input.

As the second control signal IOSTB is activated to a high level, a low-level redundancy flag XRFLG may be output to a device external to the semiconductor apparatus 1000 through the test global line TGIO and the input/output pad DQ.

Based on a low-level redundancy flag XRFLG that differs from an expected value, the test equipment may determine that an error in the repair operation has occurred.

A person skilled in the art to which the present disclosure pertains can understand that the present disclosure may be carried out in other specific forms without changing its technical spirit or essential features. Therefore, it should be understood that the embodiments described above are illustrative in all aspects, not limitative. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A repair verification circuit, comprising:
a repair address storage circuit configured to store at least one repair address and configured to generate a comparison result merge signal by comparing the at least one repair address with an external input address; and
a redundancy flag generation circuit configured to generate a redundancy flag by latching the comparison result merge signal in response to a first control signal generated according to an active command.

2. The repair verification circuit of claim 1, wherein the repair address storage circuit comprises:
a plurality of address latch sets configured to store the at least one repair address and configured to generate a plurality of comparison result signal sets by comparing the at least one repair address with the external input address; and
a comparison result merge circuit configured to generate the comparison result merge signal based on the plurality of comparison result signal sets.

3. The repair verification circuit of claim 2, wherein each of the plurality of address latch sets includes a plurality of address latches, and
wherein each of the plurality of address latches comprises:
a latch configured to store a first bit of a first repair address of the at least one repair address; and
a comparison circuit configured to output a first bit of a first comparison result signal set of the plurality of comparison result signal sets by comparing the first bit of the first repair address with a first bit of the external input address.

4. The repair verification circuit of claim 2, wherein the comparison result merge circuit is configured to logically combine each of the plurality of comparison result signal sets to generate a plurality of preliminary merge signals and configured to output the comparison result merge signal based on performing a logical combination on the plurality of preliminary merge signals.

5. The repair verification circuit of claim 1, wherein the redundancy flag generation circuit comprises:
a first logic gate configured to output an inverted signal of the comparison result merge signal;
a second logic gate configured to pass an output of the first logic gate in accordance with a first phase adjustment control signal generated by inverting the first control signal;
a first latch configured to latch an output of the second logic gate in accordance with the first phase adjustment control signal;
a third logic gate configured to output an inverted signal of the output of the first latch according to the first phase adjustment control signal; and
a second latch configured to latch an output of the third logic gate in accordance with the first phase adjustment control signal to generate the redundancy flag.

6. The repair verification circuit of claim 1, further comprising a redundancy flag output circuit configured to output the redundancy flag through a test global line in response to a second control signal generated in accordance with a read command.

7. The repair verification circuit of claim 6, wherein the redundancy flag output circuit comprises:
a driving circuit configured to pull the test global line up to a power level or pull the test global line down to a ground level; and
a driving control circuit configured to control an operation of the driving circuit in accordance with the redundancy flag and the second control signal.

8. The repair verification circuit of claim 6, further comprising a selection circuit configured to, based on a test mode signal, output either a signal transmitted through a global line or a signal transmitted through the test global line to an input/output pad.

9. A semiconductor apparatus, comprising:
a memory core including a plurality of memory cells;
a repair verification circuit configured to compare an external input address with at least one repair address to generate a comparison result merge signal, configured to latch the comparison result merge signal in accordance with a first control signal generated in response to an active command to generate a redundancy flag, and configured to output the redundancy flag in accordance with a second control signal generated in response to a read command; and
an OTP memory circuit configured to store the at least one repair address corresponding to at least one memory cell determined to be defective among the plurality of memory cells and configured to transmit the at least one stored repair address to the repair verification circuit.

10. The semiconductor apparatus of claim 9, further comprising:
an input/output pad circuit including a plurality of pads; and
a data input/output circuit configured to be coupled to the memory core through a global line, configured to be coupled to the repair verification circuit through a test global line, and configured to output one of a signal from the global line and the redundancy flag transmitted through the test global line to one of the plurality of pads in response to a test mode signal.

11. The semiconductor apparatus of claim 9, wherein the repair verification circuit comprises:
a repair address storage circuit configured to generate the comparison result merge signal by comparing the at least one repair address with the external input address;
a redundancy flag generation circuit configured to generate the redundancy flag by latching the comparison result merge signal in response to the first control signal; and
a redundancy flag output circuit configured to output the redundancy flag to a test global line in response to the second control signal.

12. The semiconductor apparatus of claim 11, wherein the repair address storage circuit comprises:
a plurality of address latch sets configured to store the at least one repair address and configured to generate a plurality of comparison result signal sets by comparing the at least one repair address with the external input address; and
a comparison result merge circuit configured to generate the comparison result merge signal based on the plurality of comparison result signal sets.

13. The semiconductor apparatus of claim 12, wherein each of the plurality of address latch sets includes a plurality of address latches, and
wherein each of the plurality of address latches comprises:
a latch configured to store a first bit of a first repair address of the at least one repair address; and
a comparison circuit configured to output a first bit of a first comparison result signal set of the plurality of comparison result signal sets by comparing the first bit of the first repair address with a first bit of the external input address.

14. The semiconductor apparatus of claim 12, wherein the comparison result merge circuit is configured to logically combine each of the plurality of comparison result signal sets to generate a plurality of preliminary merge signals, and configured to output the comparison result merge signal based on performing a logical combination on the plurality of preliminary merge signals.

15. The semiconductor apparatus of claim 11, wherein the redundancy flag generation circuit comprises:
a first logic gate configured to output an inverted signal of the comparison result merge signal;
a second logic gate configured to pass an output of the first logic gate in accordance with a first phase adjustment control signal generated by inverting the first control signal;
a first latch configured to latch an output of the second logic gate in accordance with the first phase adjustment control signal;
a third logic gate configured to output an inverted signal of the output of the first latch according to the first phase adjustment control signal; and
a second latch configured to latch an output of the third logic gate in accordance with the first phase adjustment control signal to generate the redundancy flag.

16. The semiconductor apparatus of claim 11, wherein the redundancy flag output circuit comprises:
a driving circuit configured to pull the test global line up to a power level or pull the test global line down to a ground level; and
a driving control circuit configured to control an operation of the driving circuit in accordance with the redundancy flag and the second control signal.

17. The semiconductor apparatus of claim 9, wherein the OTP memory circuit includes a plurality of electronic fuses and is configured to program and store the at least one repair address in the plurality of electronic fuses.

18. The semiconductor apparatus of claim 9, wherein the OTP memory circuit is configured to transmit the at least one repair address to the repair verification circuit in a boot-up period of the semiconductor apparatus.
